(19) United States
(12) Patent Application Publication
(10) Pub. No.: US 2017/0259935 A1
(43) Pub. Date: Sep. 14, 2017

(54) RECONFIGURABLE FLIGHT GUIDANCE PANELS FOR TRANSPORT CATEGORY AIRCRAFT

(71) Applicant: Gulfstream Aerospace Corporation, Savannah, GA (US)

(72) Inventors: Jeffrey Hausmann, Savannah, GA (US); Scott Buethe, Savannah, GA (US); Andrew Martin, Savannah, GA (US)

(73) Assignee: Gulfstream Aerospace Corporation, Savannah, GA (US)

(21) Appl. No.: 15/453,005

(22) Filed: Mar. 8, 2017

Related U.S. Application Data
(60) Provisional application No. 62/305,246, filed on Mar. 8, 2016.

(51) Int. Cl. B64D 43/00; G06F 3/041; G06F 3/0362

(52) U.S. Cl. CPC B64D 43/00; G06F 3/0362; G06F 3/041; H03K 17/945

(57) ABSTRACT

Flight guidance panels and vehicle guidance panels are provided. A flight guidance panel for an aircraft includes a hardware knob, a display proximate the hardware knob, and a controller. The controller is configured for: altering an automation state of the aircraft; receiving a target of a flight parameter for the aircraft to achieve when the automation state is active; and generating a functional panel associated with the flight parameter and the hardware knob based on a configuration of the flight guidance panel.

### CROSS-REFERENCE TO RELATED APPLICATIONS

This application claims the benefit of U.S. Provisional Application No. 62/305,246, filed Mar. 8, 2016. The disclosure of the above application is incorporated herein by reference.

### TECHNICAL FIELD

The present invention generally relates to aircraft avionics, and more particularly relates to reconfigurable flight guidance panels for transport category aircraft.

### BACKGROUND

Conventional transport category flight guidance panels are primarily implemented in hardware. Knobs and buttons control specific functions and the functions are stenciled on the panel itself Annunciations are provided using lamps or lights. Selections are displayed using numerical readouts. The implementation in hardware results in the conventional flight guidance panels being difficult to change or adapt to installation in aircraft other than those for which the conventional flight guidance panel was designed. Such custom design is time consuming and costly when designing new aircraft. Furthermore, conventional flight guidance panels are limited to the functionality originally designed in hardware, where additional functionality is difficult to integrate.

Accordingly, it is desirable to provide systems and methods for reconfigurable flight guidance panels. Furthermore, other desirable features and parameters of the present invention will become apparent from the subsequent detailed description of the invention and the appended claims, taken in conjunction with the accompanying drawings and this background of the invention.

### BRIEF SUMMARY

Various non-limiting embodiments of flight guidance panels and vehicle guidance panels are disclosed herein.

In a first non-limiting embodiment, a flight guidance panel for an aircraft includes, but is not limited to, a hardware knob, a display proximate the hardware knob, and a controller. The controller is configured for: altering an automation state of the aircraft; receiving a target of a flight parameter for the aircraft to achieve when the automation state is active; and generating a functional panel associated with the flight parameter and the hardware knob based on a configuration of the flight guidance panel.

In a second non-limiting embodiment, a vehicle guidance panel includes, but is not limited to, a hardware knob, a display proximate the hardware knob, and a controller. The controller is configured for: altering an automation state of a vehicle; receiving a target of a motion parameter for the vehicle to achieve when the automation state is active; and generating a functional panel associated with the motion parameter and the hardware knob based on a configuration of the vehicle guidance panel.

### BRIEF DESCRIPTION OF THE DRAWINGS

The present invention will hereinafter be described in conjunction with the following drawing figures, wherein like numerals denote like elements, and

FIGS. 1 and 2 are simplified schematic views illustrating non-limiting embodiments of a flight guidance panel in accordance with the teachings of the present disclosure; and

FIG. 3 is a flow diagram illustrating a non-limiting embodiment of a method of operating a flight guidance panel in an aircraft in accordance with the teachings of the present disclosure.

### DETAILED DESCRIPTION

The following detailed description is merely exemplary in nature and is not intended to limit the invention or the application and uses of the invention. Furthermore, there is no intention to be bound by any theory presented in the preceding background or the following detailed description.

Flight Guidance Panels (FGPs) described herein generally implement functions in software to provide design flexibility, upgradability, and opportunity to offer the FGP as a retrofit option for currently fielded aircraft. A transport category flexible flight guidance panel uses software controlled displays, knobs, and buttons to allow use of the panel in multiple aircraft types by changing software. Examples of FGPs presented herein use software to define and annunciate functions and selections. In some embodiments, color displays also are utilized to explicitly communicate the state of the FGP to the flight crew. Although the FGP is discussed herein as a component of an aircraft, the configurations and algorithms described for operation of the FGP may be applicable to other vehicles, such as submarines or automobiles.

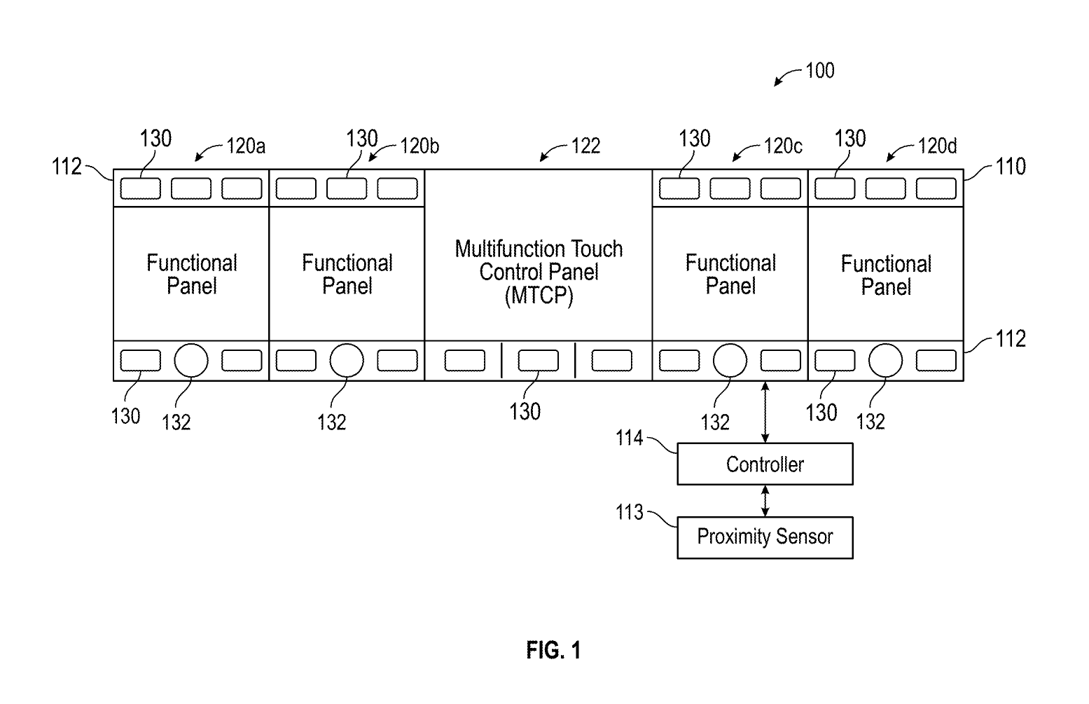

FIG. 1 is schematic view illustrating a non-limiting embodiment of a flight guidance panel (FGP) 100 in accordance with teachings of the present disclosure. FGP 100 includes a display 110, a hardware input portion 112, a proximity sensor 113, and a controller 114.

Display 110 includes a first functional panel 120A, a second functional panel 120B, a third functional panel 120C, a fourth functional panel 120D, and a Multifunction Touchscreen Control Panel (MTCP) 122. Functional panels 120A-D are each associated with a navigational parameter of flight, such as airspeed, heading, course, vertical speed, altitude, or other parameters typically associated with flight guidance panels. As used herein, the term “functional panel” means a portion of display 100 that includes only information that is related to the flight parameter and automation modes that may manage the flight parameter.

Each of panels 120A-D and 122 is sunlight readable, is full color, has sufficient resolution to clearly render text when the flight crew is seated at design eye, and features power and display driver redundancy to provide robust availability. For example, panels 120A-D may be implemented as organic light emitting diode (OLED) panels, light emitting diode (LED) panels, or any other suitable display technology.

In the example provided, panels 120A-D and 122 are vertically aligned and are in alphabetical order from left to right in FGP 100, with multi-function panel 122 disposed between functional panels 120B and 120C. In the example provided, functional panels 120A-D are implemented as four separate displays. It should be appreciated that functional panels 120A-D may be implemented as two displays on separate pieces of glass further divided by software, may be implemented on the same display on the same piece of glass as multi-function panel 122, or may be implemented in other configurations without departing from the scope of the present disclosure. In the example provided, multi-function panel 122 is larger than panels 120A-D and is touch enabled to receive user inputs by touching the face of multi-function panel 122.

Proximity sensor 113 is configured to sense the approach of a crewmember's hand towards the panel. Proximity sensor 113 may use any known technology to detect the approach of the crewmember hand or other object, as will be appreciated by those with ordinary skill in the art. In the example provided, controller 114 utilizes proximity sensor 113 to control the amount of information displayed on display 110, as will be described below.

Hardware input portion 112 includes at least one hardware button 130 and at least one hardware knob 132 to receive crew inputs for use by controller 114. In the example provided, hardware buttons 130 are aligned in rows along the top and bottom peripheries of each panel 120A-D and 122. Hardware buttons 130 are physical buttons with associated functions and labels implemented in software. In the example provided, each functional panel 120A-D has five hardware buttons 130 arranged as three across the top and two across the bottom. Hardware buttons in addition to those required for any particular implementation may be provided to address emerging requirements and future growth. In the example provided, three hardware buttons 130 are associated with multi-function panel 122 along the bottom of FGP 100. It should be appreciated that the number and locations of hardware buttons 130 may vary without departing from the scope of the present disclosure. In some embodiments, hardware buttons 130 are omitted and buttons may be implemented as virtual buttons implemented in software.

Each functional panel 120A-D is associated with a dedicated hardware knob 132 to permit a crewmember adjustment of the flight parameter displayed on the respective functional panel 120A-D. Hardware knobs 132 rotate to provide simple adjustment of, for example, numerical values associated with automation targets of the flight parameter. In the example provided, hardware knobs 132 also depress to permit additional crewmember input functions.

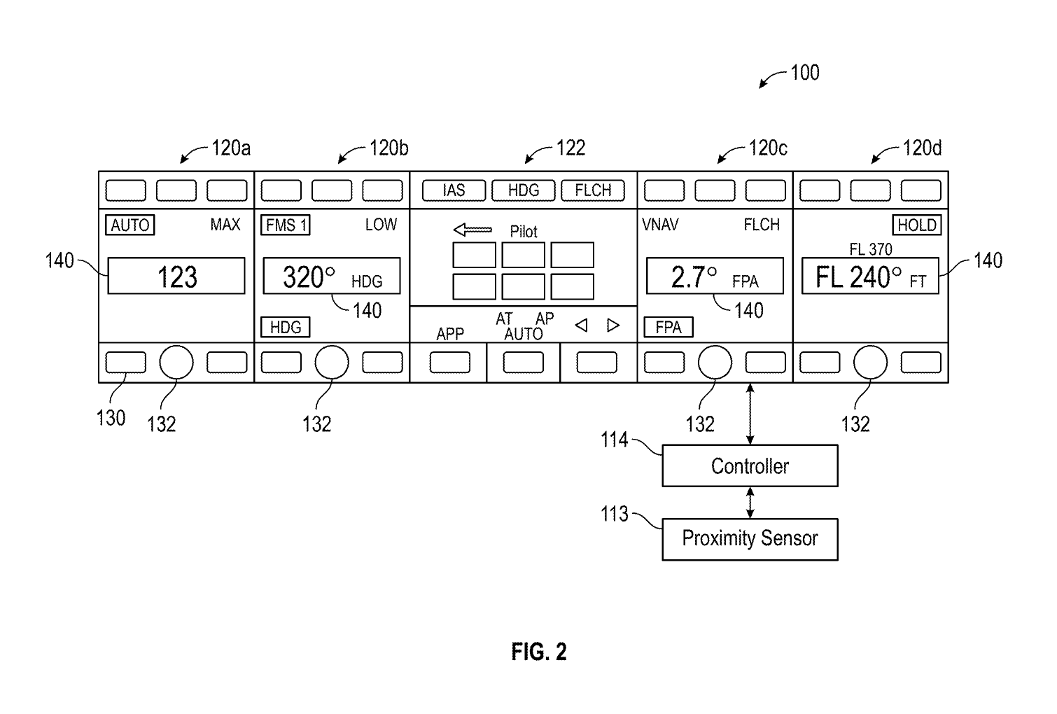

Referring now to FIG. 2, controller 114 is a hardware device that carries out instructions of a computer program to perform the functions of FGP 100. Controller 114 is a specific purpose computer configured to execute the computer program to provide the functions described herein. Controller 114 includes one or more memory units that store electronic data and computer programs. For example, the memory units may be flash memory, spin-transfer torque random access memory (STT-RAM), magnetic memory, phase-change memory (PCM), dynamic random access memory (DRAM), or other suitable electronic storage media. In the example provided, the memory units store control logic with instructions that cooperate with a processor of controller 114 to perform operations of the method described below. In some embodiments, the processor may include one or more central processing units (“CPUs”), a microprocessor, an application specific integrated circuit (“ASIC”), a microcontroller, and/or other suitable device. Furthermore, controller 114 may utilize multiple hardware devices as is also appreciated by those skilled in the art.

Controller 114 is configured to provide the functions associated with a flight guidance panel in addition to the specific features described below. In general, controller 114 receives inputs, calculates instructions, and generates instructions for display 110 to present information related to the state of the aircraft.

Controller 114 is configured to define the function of various hardware buttons 130 as well as to cause display 110 to present labels for various hardware buttons 130 that are assigned functions. In the example provided, the function label for the various hardware buttons 130 is displayed proximate to and immediately adjacent to the button, either above or below the button based on button location. In the example provided, controller 114 configures hardware buttons 130 in functional panels 120A-D to operate in one of two ways. First, a hardware button 130 may immediately select an option for an automation mode change, such as Flight Level Change (FLCH) on the Vertical panel. Second, a button may toggle between one of two options. The lower right hand button 130 on the functional panels 120A and 120D operate this way, toggling between available display units (e.g., KT/Mach for speed, FT/Meters for altitude). In some embodiments, controller 114 commands display 110 to present an automation state label adjacent to the hardware button, buttons may be depressed to indicate an automation state change input, and controller 114 may be configured for changing an automation state of the aircraft in response to receiving the automation state change input.

The function of hardware knobs 132 is determined by controller 114. In some embodiments, controller 114 is configured for changing an automation target of the flight parameter in response to rotation of the hardware knob. In the example provided, rotating a knob counterclockwise reduces the value the knob is controlling and rotating a knob clockwise increases the value the knob is controlling. The center of each knob can be depressed. In the example provided, pressing the ‘SYNC’ button on the Speed, Lateral, and Vertical knobs will place the aircraft's current value of that parameter in the center of each display. Pressing the center button on the Altitude knob will let the crew toggle between controlling the altitude value by the hundreds digit or thousands digit. Once the aircraft is above the Transition Altitude, the thousands mode will automatically be selected.

As mentioned above, each functional panel 120A-D is associated with a flight parameter. As used herein, the term “flight parameter” refers to a value quantifying the movement of an aircraft and that may be controlled or managed by an autopilot of the aircraft. In general, each functional panel 120A-D presents a target value for the flight parameter and selectors for changing which automation mode is active in FGP 100.

The parameter displayed for each functional panel 120A-D may be changed by use of MTCP 122. For example, controller 114 may be configured for changing the functional panel and the flight parameter associated with the hardware knob in response to a reconfiguration input at the MTCP. In the example provided, first functional panel 120A is a speed panel (“Speed”), second functional panel 120B is a lateral navigation panel (“Lateral”), third functional panel 120C is a vertical navigation panel (“Vertical”), and fourth functional panel 120D is an altitude panel (“Altitude”), as will be appreciated by those with ordinary skill in the art.

In the example provided, the top portion of the functional panel is where the available modes for that functional panel are selected and displayed. In some functional panels, such as the Vertical panel, the modes may be directly selected when they are mutually exclusive. VNAV, FPA, or Flight Level Change (FLCH) may be selected. In contrast, the upper button of the Speed panel toggles between Auto and Manual speeds and the button of the Altitude Panel where altitude Hold can either be manually selected or simply annunciated once the pre-selected altitude has been automatically captured. In the example provided, the bottom buttons toggle between units on the Speed, Vertical, and Altitude panels, and between Heading and Track on the Lateral panel. It should be appreciated that the number of buttons and the functions of each button may vary without departing from the scope of the present disclosure.

Each functional panel 120A-D includes an automation state indicator and a tracked condition indicator. The automation state indicator conveys whether automation is active for the flight parameter. The tracked condition indicator conveys whether an aircraft is currently operating at the target for the flight parameter. In the example provided, a rectangle 140 in the central portion of each functional panel 120A-D serves as the automation state indicator and the tracked condition indicator. The value inside each rectangle 140 shows what FGP 100 is doing right now. In the example provided, the rectangle 140 itself may indicate one of four states. The first state is an “automation following” state that indicates aircraft automation is actively maintaining the value indicated in the functional panel. In the example provided, the automation following state is indicated by a solid green border in functional panels 120C-D of FIG. 2.

The second state is a “manual director” state where a flight director is provided for use in a primary flight display, but automation is off and the crew is responsible for actively managing the value with the inceptor, throttles, or other manual flight control object. In the example provided, functional panel 120B illustrates the manual director state. The third state is an “information only” state that indicates the crew is responsible for managing the value and no flight director is provided. In the example provided, the information only state is indicated by a lack of rectangle or black rectangle that matches the background of the functional panel.

The fourth state is an “automation not tracking” state that indicates the automation is responsible for managing the value, but is not currently tracking the desired value. For example, the automation not tracking state may be presented when the value was recently changed or when the aircraft is not able to maintain the value (e.g., not enough power to maintain target airspeed at tracked vertical flight path angle). In the example provided, the automation not tracking state is indicated by a green reverse video where the fill of rectangle 140 has a green fill, as illustrated in functional panel 120A of FIG. 2.

Proximity sensor 113 may utilize any suitable technology to determine the presence or absence of an object proximate display 110, as will be appreciated by those with ordinary skill in the art. In the example provided, controller 114 utilizes proximity sensor 113 to display all labels and options that allow you to interact with panel and change the aircraft state when an object is detected. When proximity sensor 113 does not detect an object, controller 114 commands display 100 to present a minimized condition that displays the state of the aircraft but does not present options for changing the state. For example, the button labels may be omitted in the minimized condition. In other words, controller 114 utilizes proximity sensor 113 to declutter or reduce visual clutter by suppressing the display of items that are not pertinent in the present phase of flight.

MTCP 122 is configured by controller 114 to control several different functions. In the example provided, the APR button selects the Approach mode if available. Pressing the AP/AT button will engage both the Autopilot and Autothrottles. A subsequent push will disengage the Autopilot but leave the Autothrottles engaged. In the example provided, the Autothrottles may only be disengaged by using the buttons on the Throttles of the aircraft. The Autopilot can also be disengaged by using the disengage switch on the flight controls inceptor of the aircraft. Finally, the Primary Flight Display Source (PFD SRC) button toggles the FGP navigation source between the pilot and copilot.

It should be appreciated that other functions may be controlled by multi-function panel 122. For example, MTCP 122 may control: selection of lateral navigation source; mirroring Primary Flight Display mode selectors and status; display and entry of data link commands related to the FGP; and various clocks and timers. MTCP may further be configured to perform the functions of a functional panel 120A-D to provide dispatch capability in the event of a failed functional panel.

In some embodiments, controller 114 may be configured to command the display to present the flight parameter, virtual buttons, and labels as a skeuomorph of an original component of an aircraft into which the flight guidance panel may be disposed as a replacement flight guidance panel. Accordingly, the number of replacement parts that must be stocked to service older model aircraft may be reduced.

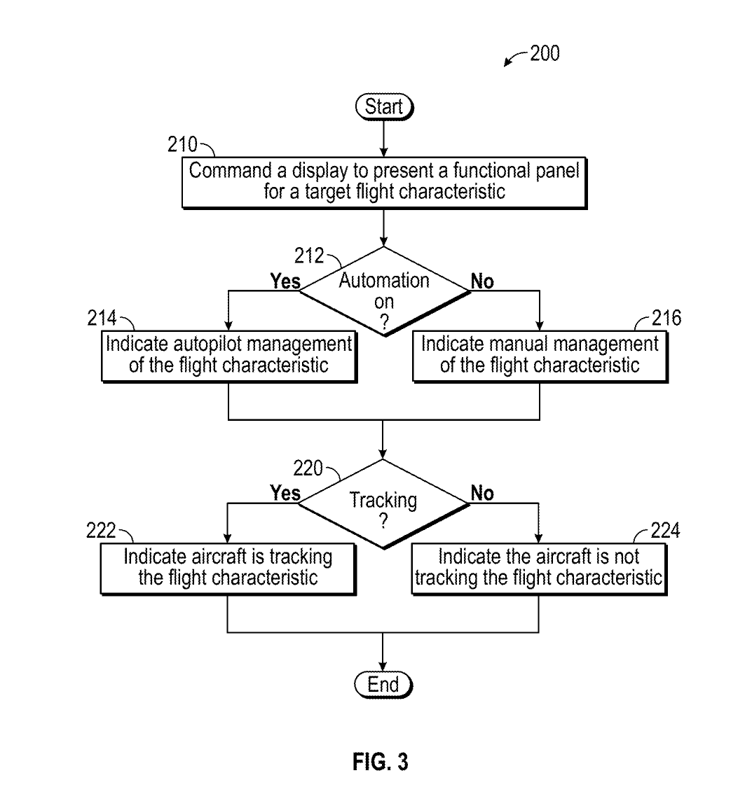

Referring now to FIG. 3, and with continued reference to FIGS. 1-2, a method 200 of operating a flight guidance panel in an aircraft is illustrated. In the example provided, tasks of method 200 are performed by controller 114 in cooperation with display 110, hardware input portion 112, and proximity sensor 113.

A controller commands a display to present a functional panel for a target flight parameter in task 210. For example, controller 114 may command display 110 to present functional panels 120A-D. The controller determines whether automation is on in task 212. For example, controller 114 may determine the automation mode for a given functional panel and flight parameter.

When automation is on, method 200 proceeds to task 214 where the controller indicates that the flight parameter is managed by the autopilot. When automation is not on, method 200 proceeds to task 216 to indicate that the flight parameter is managed manually. For example, controller 114 may present the automation state indicator as rectangle 140 with different colors in tasks 214 and 216.

The controller determines whether the aircraft is currently operating at (“tracking”) the flight parameter in task 220. When the aircraft is tracking the flight parameter, the controller indicates that the aircraft is tracking in task 222. When the aircraft is not tracking the flight parameter, the controller indicates that the aircraft is not tracking in task 224. For example, controller 114 may indicate that the aircraft is tracking the flight parameter by the lack of colored fill within rectangle 140 or may indicate that the aircraft is not tracking the flight parameter by the presence of colored fill within rectangle 140.

The embodiments described herein offer multiple advantages over conventional flight guidance panels. For example, implementing functionality in software versus hardware allows for more flexibility in the development process and accommodate a broad range of crew preferences by allowing end-user customization (e.g. simultaneous display of dual values such as CAS and Mach, Heading and Track, etc).

While at least one exemplary embodiment has been presented in the foregoing detailed description of the invention, it should be appreciated that a vast number of variations exist. It should also be appreciated that the exemplary embodiment or exemplary embodiments are only examples, and are not intended to limit the scope, applicability, or configuration of the invention in any way. Rather, the foregoing detailed description will provide those skilled in the art with a convenient road map for implementing an exemplary embodiment of the invention. It being understood that various changes may be made in the function and arrangement of elements described in an exemplary embodiment without departing from the scope of the invention as set forth in the appended claims.

What is claimed is:

1. A flight guidance panel for an aircraft, the flight guidance panel comprising:
a hardware knob;
a display proximate the hardware knob; and
a controller configured for:
altering an automation state of the aircraft;
receiving a target of a flight parameter for the aircraft to achieve when the automation state is active; and
generating a functional panel associated with the flight parameter adjacent to the hardware knob based on a software configuration of the flight guidance panel.

2. The flight guidance panel of claim 1, wherein the controller is further configured for changing the target of the flight parameter in response to rotation of the hardware knob.

3. The flight guidance panel of claim 1, wherein the controller is further configured for changing the automation state of the aircraft in response to receiving an automation state change input.

4. The flight guidance panel of claim 3, further comprising a hardware button, and wherein the controller is further configured to command the display to present an automation state label adjacent to the hardware button, and to receive the automation state change input in response to depression of the hardware button.

5. The flight guidance panel of claim 1, further comprising a proximity sensor, and wherein the controller is further configured to declutter the functional panel in response to the proximity sensor detecting that an object is not in proximity to the flight guidance panel.

6. The flight guidance panel of claim 5, wherein the controller is further configured to command the display to present options for changing the automation state and for interacting with the flight guidance panel in response to the proximity sensor detecting an approach of the object.

7. The flight guidance panel of claim 1, wherein the controller is further configured to command the display to present an automation state indicator that conveys whether automation is active for the flight parameter.

8. The flight guidance panel of claim 1, wherein the controller is further configured to command the display to present a tracked condition indicator that conveys whether the aircraft is currently operating at the target.

9. The flight guidance panel of claim 1, wherein the controller is further configured to command the display to present the flight parameter, virtual buttons, and labels as a skeuomorph of an original component of the aircraft into which the flight guidance panel may be disposed as a replacement flight guidance panel.

10. The flight guidance panel of claim 1, wherein the display further includes a multifunction touch control panel (MTCP) portion, and wherein the controller is further configured for changing the functional panel and the flight parameter associated with the hardware knob in response to a reconfiguration input at the MTCP portion.

11. The flight guidance panel of claim 1, wherein the functional panel is one of a speed panel, a lateral panel, a vertical panel, and an altitude panel.

12. A vehicle guidance panel comprising:
a hardware knob;
a display proximate the hardware knob; and
a controller configured for:
altering an automation state of a vehicle;
receiving a target of a motion parameter for the vehicle to achieve when the automation state is active; and
generating a functional panel associated with the motion parameter and the hardware knob based on a configuration of the vehicle guidance panel.

13. The vehicle guidance panel of claim 12, wherein the controller is further configured for changing the target of the motion parameter in response to rotation of the hardware knob.

14. The vehicle guidance panel of claim 12, wherein the controller is further configured for changing the automation state of the vehicle in response to receiving an automation state change input.

15. The vehicle guidance panel of claim 14, further comprising a hardware button, and wherein the controller is further configured to command the display to present an automation state label adjacent to the hardware button, and to receive the automation state change input in response to depression of the hardware button.

16. The vehicle guidance panel of claim 12, further comprising a proximity sensor, and wherein the controller is further configured to declutter the functional panel in response to the proximity sensor detecting that an object is not in proximity to the vehicle guidance panel.

17. The vehicle guidance panel of claim 16, wherein the controller is further configured to command the display to present options for changing the automation state and interacting with the vehicle guidance panel in response to the proximity sensor detecting an approach of the object.

18. The vehicle guidance panel of claim 12, wherein the controller is further configured to command the display to present an automation state indicator that conveys whether automation is active for the motion parameter.

19. The vehicle guidance panel of claim 12, wherein the controller is further configured to command the display to present a tracked condition indicator that conveys whether the vehicle is currently operating at the target.

20. The vehicle guidance panel of claim 12, wherein the display further includes a multifunction touch control panel (MTCP) portion, and wherein the controller is further configured for changing the functional panel and the motion parameter associated with the hardware knob in response to a reconfiguration input at the MTCP portion.
